(19) United States
(12) Patent Application Publication
(10) Pub. No.: US 2012/0058597 A1
(43) Pub. Date: Mar. 8, 2012

(54) FABRICATION METHOD FOR THIN-FILM FIELD-EFFECT TRANSISTORS

(75) Inventors: Thomas Anthopoulos, London (GB); Donal Donat Conor Bradley, Buckinghamshire (GB); Jeremy Nicholas Smith, London (GB)

(73) Assignee: IMPERIAL INNOVATIONS LIMITED, London (GB)

(21) Appl. No.: 13/002,113

(22) PCT Filed: Jun. 30, 2009
(86) PCT No.: PCT/GB09/01635

§ 371 Date: Jan. 26, 2011

(30) Foreign Application Priority Data
Jun. 30, 2008 (GB) 0811962.0

(51) Int. Cl. H01L 21/34

(52) U.S. Cl. 438/104; 257/E21.46

(57) ABSTRACT

A thin-film field-effect transistor is formed by forming a dielectric layer adjacent a gate, forming a source region and a drain region, and forming a semiconductor layer on the dielectric layer. The semiconductor layer is deposited by spray pyrolysis and comprises a material selected from a group comprising: oxides; oxide-based materials; mixed oxides; metallic type oxides; group I-IV, II-VI, III-VI, IV-VI, V-VI and VIII-VI binary chalcogenides; and group I-II-VI, II-II-VI, II-III-VI, II-VI-VI and V-II-VI ternary chalcogenides.

This invention relates to thin-film field-effect transistors and a fabrication method thereof.

### BACKGROUND TO THE INVENTION

Semiconducting thin-film transistors (TFTs) comprise a substrate, a semiconducting layer, a dielectric layer, and conducting materials for the source, drain and gate electrodes. Depending on the gate potential (V_{G}) and the drain potential (V_{D}), the channel current (i.e. the current flowing from the source electrode to the drain electrode, often referred to as I_{D}) can be modulated.

Over the last ten years, TFTs based on amorphous inorganic semiconductors have become the key technology for numerous applications. The most notable example comes from the information display industry where amorphous (a-Si) transistors, in particular, are found at the heart of everyday products including electrophoretic displays (i.e. E-paper), liquid crystal displays (LCDs), liquid crystal on silicon (LCoS) for micro-display and projection TV technology, to name a few.

Generally, amorphous semiconductors are preferred over polycrystalline films as the active layers from the view point of processing temperature and uniformity of device characteristics, i.e. small parameter spread. Despite the significant advantages, however, use of a-Si or state-of-the-art organic materials in the next generation displays is limited mainly due to their low carrier mobility (0.01-1 cm²/Vs). For example, with the use of amorphous semiconductors in current driven display technologies such as active-matrix (AM) displays based on organic light-emitting diodes (OLEDs), small mobilities mean that the transistors must be large enough in order to drive the necessary current (1-10 μA/pixel). In reality, however, driving TFTs cannot exceed certain dimensions because the bigger their size the smaller the available area for the emitting pixel. This is the so-called aperture ratio and is defined as the fraction of the total pixel area available for light emission. In the case of a-Si TFTs or high-performance organic TFTs (OTFTs) and a pixel size of 300-500 μm, aperture ratios of 40-50% have been demonstrated.

One possible route towards increasing the aperture ratio is the use of high mobility polycrystalline semiconductors such as polycrystalline-Si (p-Si). The downside of this approach is that device processing requires a large thermal budget with typical temperatures in excess of 500° C. This not only imposes a severe restriction on the choice of substrate materials but also hampers the overall suitability of the technology for prospective low cost fabrication. Another major contributor to the limited aperture ratio is the extensive wiring needed. This because every pixel in an AM display requires additional circuitry which typically includes a switching transistor and a storage capacitor integrated with appropriate power/data lines to allow selective pixel addressing. As a result the area associated with the driving electronics becomes comparable to the area of the light-emitting, pixel, hence severely reducing the aperture ratio.

One alternative approach that could potentially address all the issues outlined above is the use of conductive and semiconductive transparent metal oxides as the electrode and active channel materials, respectively. Metal oxides have been known for many years but only recently have been explored in active electronic devices such as field-effect transistors. A very important property associated with this class of materials is that the charge transport can be independent of the crystallinity of the solid. This feature is completely different from what is usually encountered in covalent semiconductors such as Si. As a result, amorphous films of metal oxides exhibit the same carrier mobilities as crystalline films. Therefore one could envision high performance applications where the high mobility semiconductor is an amorphous oxide.

In recent years, oxide semiconductors have been the focus of intense research because of their potential in numerous technological applications including photocatalysis, solar cells, light-emitting diodes, and very recently, TFTs. In the past, a variety of techniques have been used for the deposition of oxide films, including radio frequency magnetron sputtering, pulsed laser deposition, metal organic chemical vapour deposition, dip coating, spin coating, and spray pyrolysis. With the latter three techniques the films are deposited from solution in ambient air. The advantages of solution-processing over sputtering, laser or vapour deposition techniques are known from organic electronics with the most important being the easy deposition and patterning of the semiconductor materials on large area substrates employing relatively simple techniques. The latter could potentially lead to a significant reduction in processing cost and equipment expenditure. However, in most cases, control over the morphology of the solution-processed semiconductor films is limited and can negatively affect device performance. As result there is a desire to simplify the fabrication process for TFTs, particularly those using oxide semiconductors.

### SUMMARY OF THE INVENTION

According to a first aspect of the present invention there is provided a method as defined in claim 1 of the appended claims. Thus there is provided a method of forming a thin-film field-effect transistor comprising: forming a dielectric layer adjacent a gate; forming a source region and a drain region; and forming a semiconductor layer on the dielectric layer; wherein the semiconductor layer is deposited by spray pyrolysis and comprises a material selected from a group comprising: oxides; oxide-based materials; mixed oxides; metallic type oxides; group I-IV, II-VI, III-VI, IV-VI, V-VI and VIII-VI binary chalcogenides; and group I-II-VI, II-II-VI, II-III-VI, II-VI-VI and V-II-VI ternary chalcogenides.

The order in which the various processes appear in the preceding sentence should not be interpreted as implying any particular sequence of steps in the formation of the transistor.

Accordingly, the invention enables the fabrication of oxide-based TFTs in which the semiconductor layer(s) is/are deposited by spray pyrolysis.

Deposition of the source and/or drain regions, and/or the gate, can also be performed by spray pyrolysis, using appropriate conductive materials such as conductive oxides made using doped metal oxides (e.g. indium doped tin oxide, aluminium doped zinc oxide, to name but two).

The invention enables simple fabrication of TFTs, by exploiting the ability to deposit metal oxide (and other) semiconductors by spray pyrolysis. Spray pyrolysis is an attractive processing route for TFTs since it is scalable and hence provides a potentially low-cost process suitable for the deposition of dense films. Moreover, there are virtually no restrictions on the substrate material and dimensions. By changing the composition of the spray solution during the spraying process it can be used to make layered films of different physical characteristics, i.e. optical, electrical, mechanical etc. We believe such a fabrication process will be well-suited to the manufacture of display devices such as active-matrix displays, as well as large area integrated transparent electronics, and other devices such as light sensors, gas sensors or bio-sensors.

The use of spray pyrolysis for the fabrication of semiconductors has been surprisingly limited in the prior art. The growth of several types of oxide semiconductor films using spray pyrolysis has been reported in “Versatility of chemical spray pyrolysis technique” by P. S. Patil [Materials Chemistry and Physics 59, 185 (1999)]. However, to the best of our knowledge, to date there have been no explicit disclosures of any oxide-based TFTs fabricated by spray pyrolysis. The closest prior art known to us is WO 2006/003584 (Field-Effect Transistors), which mentions spray pyrolysis, but does not disclose oxide-based TFTs. In WO 2006/003584, the candidate materials are limited to compounds containing cadmium (Cd), zinc (Zn), lead (Pb), tin (Sn), bismuth (Bi), antimony (Sb), indium (In), copper (Cu), mercury (Hg), sulphur (S), selenium (Se) and tellurium (Te).

Also of relevance is our own International (PCT) patent application WO 2008/129238 (which was unpublished as at the priority date of the present application) relating to titanium dioxide (TiO₂) TFTs formed in a variety of ways, including spray pyrolysis.

Thus, according to a second aspect of the present invention there is provided a method of forming a thin-film field-effect transistor comprising: forming a dielectric layer adjacent a gate; forming a source region and a drain region; and forming a semiconductor layer on the dielectric layer; wherein the semiconductor layer is deposited by spray pyrolysis and comprises a material selected from a group comprising: oxides other than titanium dioxide; oxide-based materials; mixed oxides; metallic type oxides; group I-IV, II-VI, IV-VI, V-VI and VIII-VI binary chalcogenides; and group I-II-VI, II-II-VI, II-III-VI, II-VI-VI and V-II-VI ternary chalcogenides.

In relation to both the first and second aspects of the invention, preferable, optional, features are defined in the dependent claims.

Thus, preferably the semiconductor layer is deposited using a precursor solution. The precursor solution may be doped in order to incorporate dopant atoms in the semiconductor material once formed, which in turn may give rise to hole and/or electron transport and/or to higher charge carrier mobility in the semiconductor layer and/or induce/enhance additional physical properties. The dopant atoms may be selected from a group comprising: aluminium, indium, gallium, molybdenum, boron, nitrogen, lithium. Other dopants are also possible.

The spray pyrolysis may be performed at any suitable temperature according to the semiconductor material being deposited and the substrate used. The temperature may be in the range of 100° C. to 600° C., preferably in the range of 100° C. to 400° C., and more preferably in the range of 200° C. to 400° C.

The semiconductor layer may be sprayed in a raster fashion, although other deposition techniques are also possible.

The semiconductor layer may be deposited in a pulsed manner. By providing a time delay between successive sprays, this enables the solution vapours to adsorb to the substrate and convert to the semiconductor material.

Alternatively the semiconductor layer may be deposited in a continuous manner.

The method may further comprise heat treating the semiconductor layer to remove residual un-reacted precursor material(s).

In certain embodiments to be described below, the semiconductor layer is formed of zinc oxide. However, many alternative materials are possible.

Further, in certain embodiments, the source and drain regions may each be formed of titanium and gold layers, the titanium acting as an adhesion layer for the gold.

The gate may be conductive—for example, formed of a metal, or a conductive polymer, or conductive doped silicon.

To enable the fabrication of flexible devices or arrays, the gate and/or substrate and/or source and drain regions may formed of flexible materials.

The dielectric layer may be formed of an inorganic insulator, such as a metal oxide. Alternatively, the dielectric layer may be formed of an organic/polymer material, such as a perfluoropolymer, polystyrene, poly(methyl methacrylate), a crosslinkable monomer or polymer, a ferroelectric polymer, or a derivative or co-polymer of any of the above.

Some embodiments are based on top-gate transistor architectures. To form such a transistor, preferably the semiconductor layer is deposited before the dielectric layer, and the gate is formed after the dielectric layer. Preferably, the fabrication method further comprises treating the surface of the semiconductor layer with plasma (particularly preferably using oxygen plasma) prior to the deposition of the dielectric layer, as we have found that this can improve the performance of the transistor.

The method may be part of the fabrication process of a display device, an integrated (e.g. large area) electronic circuit, a memory device, or a sensor such as a UV light sensor, a gas sensor or a bio-sensor.

### BRIEF DESCRIPTION OF THE DRAWINGS

Embodiments of the invention will now be described, by way of example only, and with reference to the drawings in which:

FIG. 1 illustrates a bottom-gate bottom-contact TFT architecture according to an embodiment of the invention;

FIG. 2 illustrates the experimental setup of the spray pyrolysis technique employed in this work;

FIG. 3 illustrates (a) a schematic diagram of a bottom-gate bottom-contact ZnO TFT architecture employed, with gold source and drain electrodes; and (b) the structure of zinc acetate di-hydrate used in this work;

FIG. 4 illustrates a sequence of steps in the production of a bottom-gate bottom-contact TFT according to an embodiment of the invention;

FIG. 5 illustrates experimentally-measured output characteristics for a bottom-gate bottom-contact TFT (channel length L=10 μm, channel width W=20 mm) based on ZnO film as the semiconducting layer, deposited by spray pyrolysis at a substrate temperature of 200° C.;

FIG. 6 illustrates experimentally-measured output characteristics for a bottom-gate bottom-contact TFT (L=15 μm, W=10 mm) based on ZnO film deposited by spray pyrolysis at a substrate temperature of 300° C.;

FIG. 7 illustrates experimentally-measured output characteristics for a bottom-gate bottom-contact TFT (L=7.5 μm, W=10 mm) based on ZnO film deposited by spray pyrolysis at a substrate temperature of 400° C.;

FIG. 8 illustrates experimentally-measured transfer characteristics of a bottom-gate bottom-contact TFT (L=10 μm, W=0.75 mm) based on ZnO film deposited by spray pyrolysis at a substrate temperature of 400° C.;

FIG. 9 illustrates experimental measurements of mobility dependence on V_{G} of a bottom-gate bottom-contact TFT (L=10 μm, W=0.75 mm) based on ZnO film deposited by spray pyrolysis at a substrate temperature of 400° C., showing mobility values up to 13 cm²/Vs;

FIG. 10 illustrates a schematic diagram of a bottom-gate top-contact transistor architecture employed;

FIG. 11 illustrates experimentally-measured output characteristics for a bottom-gate top-contact TFT (L=60 μm, W=1 mm) based on ZnO film deposited by spray pyrolysis at a substrate temperature of 400° C.;

FIG. 12 illustrates experimentally-measured output characteristics of a bottom-gate top-contact TFT (L=60 μm, W=1 mm) comprising ZnO as the semiconducting layer, deposited by spray pyrolysis at 500° C., and conductive SnO₂ source and drain electrodes, also deposited by spray pyrolysis at 300° C.;

FIG. 13 illustrates the molecular structure of (a) acetamide, (b) ammonium acetate, and (c) lithium acetate dihydrate;

FIG. 14 illustrates experimentally-measured output characteristics for a bottom-gate top-contact TFT (L=60 W=1.5 mm) based on an Al doped (3%) ZnO film deposited by spray pyrolysis at a substrate temperature of 400° C.;

FIG. 15 illustrates alternative TFT architectures which may be used in further embodiments of the invention, namely (a) a bottom-gate top-contact TFT, (b) a top-gate top-contact TFT, (c) a top-gate bottom-contact TFT, (d) a top-gate TFT with asymmetric source-drain contacts, and (e) a double gate TFT; and

FIG. 16 illustrates experimentally-measured output characteristics for a top-gate bottom-contact TFT (L=30 μm, W=1 mm) based on a ZnO film deposited by spray pyrolysis at a substrate temperature of 400° C.

In the figures, like elements are indicated by like reference numerals throughout.

### DETAILED DESCRIPTION OF PREFERRED EMBODIMENTS

The present embodiments represent the best ways known to the applicants of putting the invention into practice. However, they are not the only ways in which this can be achieved.

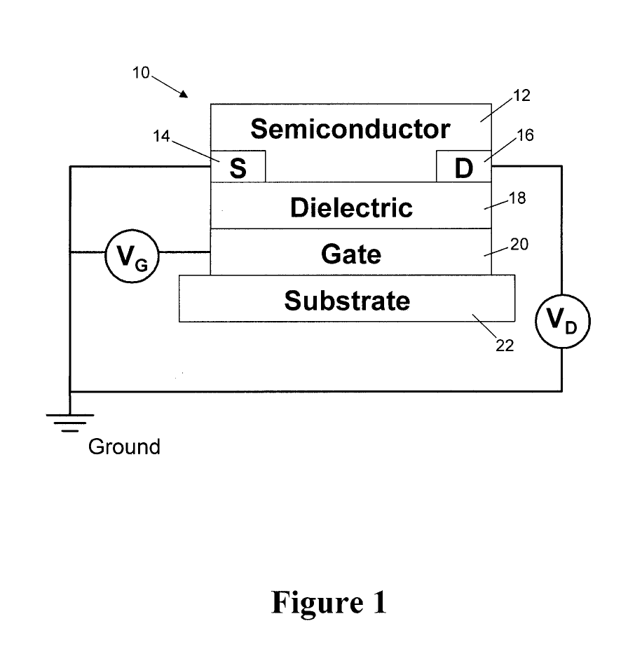

By way of introduction, as illustrated in FIG. 1, a bottom-gate bottom-contact TFT device 10 consists of a semiconducting active layer 12 applied onto a three-terminal electrode architecture comprising a source electrode 14, a drain electrode 16 and a gate electrode 20. The gate electrode 20 is separated from the semiconductor layer 12 and the source and drain electrodes by a dielectric layer 18. In embodiments of the present invention, the semiconducting layer 12 may be an oxide or oxide-based material, and is deposited using spray pyrolysis (which may be abbreviated to “SP” herein). As will be described in further detail below, alternative device architectures, other than bottom-gate bottom-contact devices, are also possible.

The embodiments of the invention seek to address both the issue of simple processing, and the control over film morphology, of the oxide semiconductor.

### Experimental Procedures

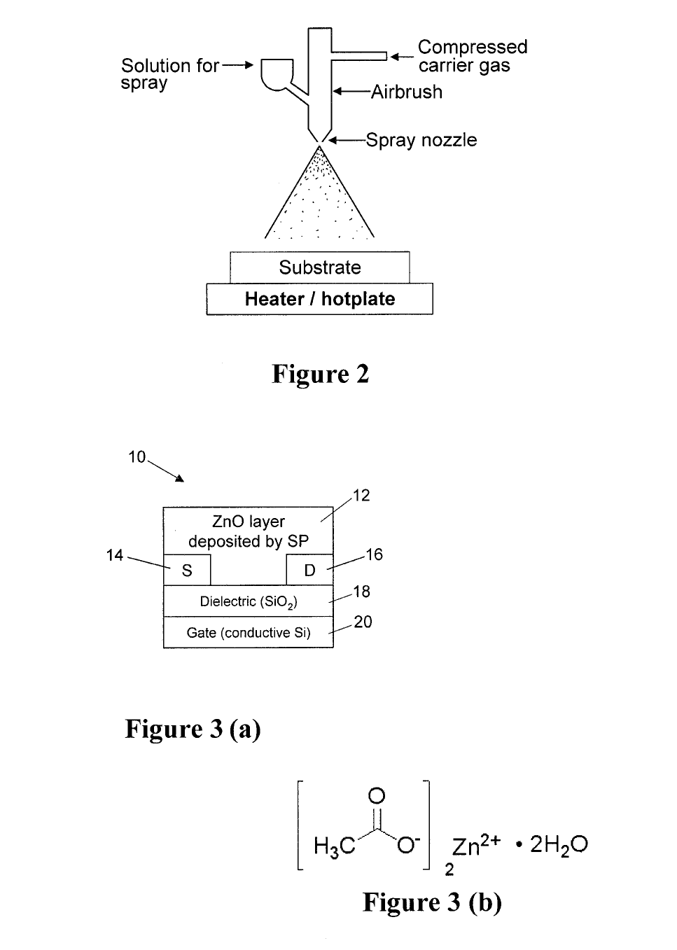

The spray pyrolysis technique may be used for the deposition of simple oxide films, mixed oxide films, metallic type oxides, group I-IV, II-VI, IV-VI, V-VI and VIII-VI binary chalcogenides, and group II-VI-VI and V-II-VI ternary chalcogenides. Films of such metal oxide and metallic spinel oxide materials prepared by SP have matching properties for a wide range of technological applications. Surprisingly, however, use of SP for the fabrication of TFTs is very limited. To provide the proof of concept we have demonstrated functional TFTs based on ZnO films deposited by SP. The experimental setup of the spray pyrolysis technique used here is shown in FIG. 2.

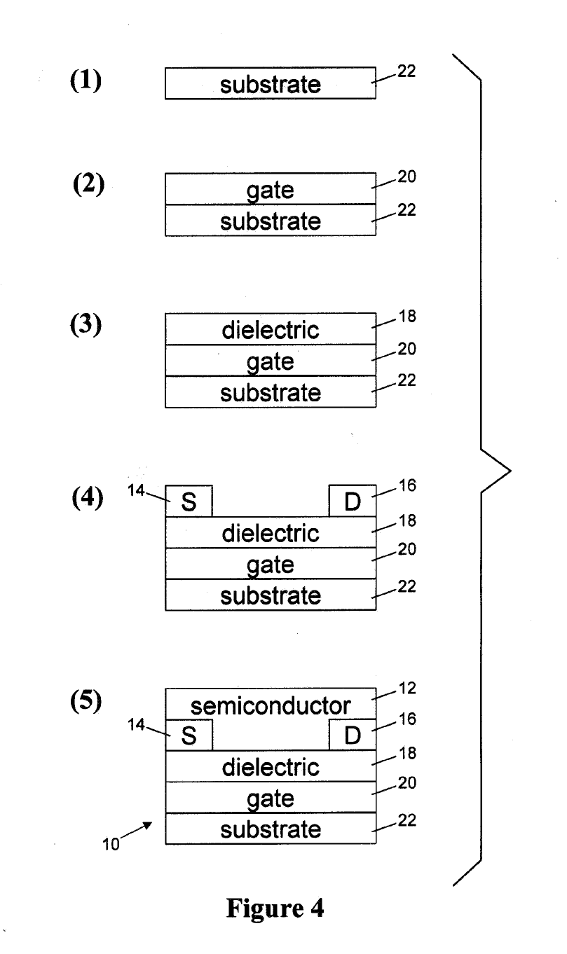

For the TFT fabrication we employed prefabricated device structures similar to the one shown in FIG. 3(a). In particular, TFTs were fabricated using heavily doped Si wafers as the global gate electrode with a 200 nm thermally oxidized SiO₂ layer as the gate dielectric. Using conventional photolithography, gold source (S) and drain (D) electrodes were defined in a bottom-gate, bottom-contact (BG-BC) configuration (FIG. 3(a)). A 10 nm layer of titanium was used, acting as an adhesion layer for the gold on SiO₂. Prior, to deposition of the ZnO channel layer, the TFT substrates were sonicated and cleaned using acetone and isopropyl alcohol. The fabrication method is illustrated schematically in FIG. 4, as steps 1 to 5, as follows:

Step (1): The substrate 22 may be rigid or flexible depending on the application. In the present embodiments highly conductive Si⁺⁺ is employed as the substrate 22, which also acts as the gate electrode 20, but this may be replaced by other materials.

Step (2): If the substrate 22 is not conducting then a conductive gate 20 has to be deposited. This can be a conductive polymer, metal, or any type of solid conductive substance (e.g. silicon, metal oxides, transparent metal oxides, etc). In the present embodiments the gate 20 is made using conductive doped silicon. However, flexible gates and substrates could also be used, made of metal foil or plastic, which would enable fabrication of flexible devices or arrays.

Step (3): The dielectric 18 is then deposited on the top of the gate 20. This is the standard process for a bottom-contact bottom-gate FET. In the present embodiments the dielectric is standard thermally-grown SiO₂. However this layer can be any inorganic material having good insulating properties, or similarly-performing organic materials (small molecules, oligomers and polymers).

Step (4): The source electrode 14 (“S”) and the drain electrode 16 (“D”) are then deposited on top of the dielectric 18. In the present embodiment the source and drain electrodes 14, 16 are each made of titanium and gold layers, the titanium and gold layers having thicknesses of 10 nm and 100 nm respectively, which are vacuum deposited and patterned using standard photolithographic techniques. Here the titanium acts as an adhesion layer for the gold, since the latter will not stick to the SiO₂ by itself. The role of the thin titanium layer is therefore not functional in terms of the electronic functionality of the device. However, other contact metals may alternatively be employed, as those skilled in the art will appreciate.

Step (5): Finally, the semiconductor layer 12 is deposited on the top of the prefabricated structure by spray pyrolysis.

In the present embodiments, deposition of the ZnO semiconductor layer was performed using a 0.2 M methanolic precursor solution of zinc acetate di-hydrate (FIG. 4b)). A thin film of ZnO as the channel layer was deposited onto pre-patterned TFT substrates (FIG. 3(a)) by spray pyrolysis at various temperatures: 100° C., 200° C., 300° C. and 400° C.

The film was grown in the following manner: The substrate was placed on the hot plate until the temperature was stabilised, then the solution was sprayed with the airbrush positioned vertically above the substrate in a raster fashion (FIG. 2). A time delay of several seconds was given before the second spray cycle (in a similar manner) to allow the solution vapours to adsorb to the substrate and convert to ZnO (or any other oxide depending on the spraying solution). The process can be repeated several times until a smooth semiconductor layer is formed.

If required, once deposited, the semiconductor layer may be heat treated to remove any residual un-reacted precursor material(s) or unwanted atmospheric molecules/atoms (e.g. oxygen, water etc.).

The source and/or drain regions, and/or the gate, can also be deposited by spray pyrolysis, using appropriate conductive materials such as conductive oxides made using doped metal oxides (e.g. indium doped tin oxide, aluminium doped zinc oxide, to name but two).

### Materials

As already described above, with the SP technique a precursor solution is pulverised by means of an inert carrier gas so that it arrives at the surface of the targeted substrate in the form of very fine droplets. Upon arrival the material droplets react chemically and convert to the desired chemical compound in the form of a film layer. The chemical reactants are selected such that the products other than the desired compound are volatile at the specific temperature so they do not stay on the surface of the substrate.

Other materials that could possibly be used as oxide semiconductors deposited by spray pyrolysis include:

| | | |
|---|---|---|
| 1. | Titanium dioxide | TiO₂ (see WO 2008/129238) |
| 2. | Magnesium oxide | MgO |
| 3. | Nickel oxide | NiO |
| 4. | Molybdenum trioxide | MoO₃ |
| 5. | Tungsten oxide | WO₃ |
| 6. | Iron oxide | FeO |
| 7. | Zirconium dioxide | ZrO₂ |

| | |
|---|---|
| 8. | Or more general AMO₂ materials where A = Silver (Ag), |
| | and M = Al, Ga |

We have proven the concept of SP deposition of oxide semiconductors to work with ZnO. Our most important findings are as follows:

### EXPERIMENTAL RESULTS

Bottom-Gate Bottom-Contact ZnO Transistors

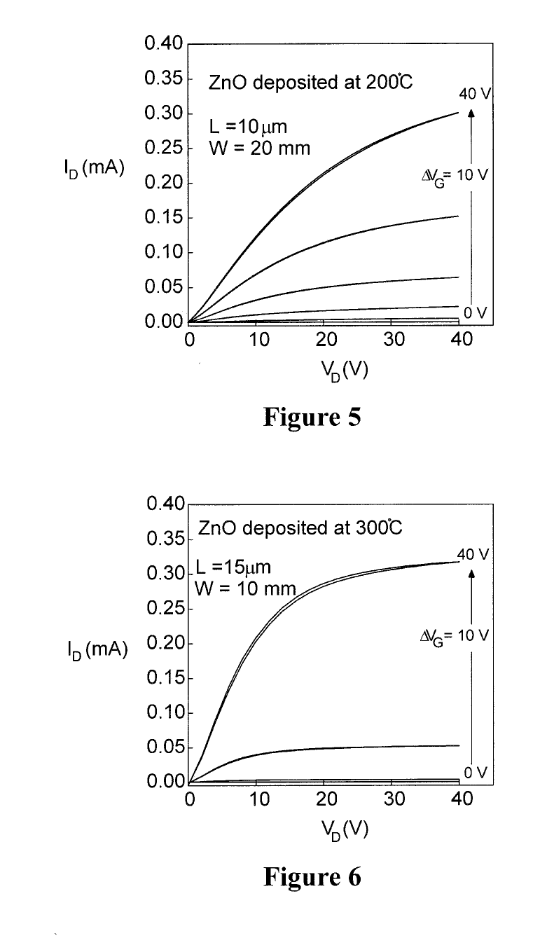

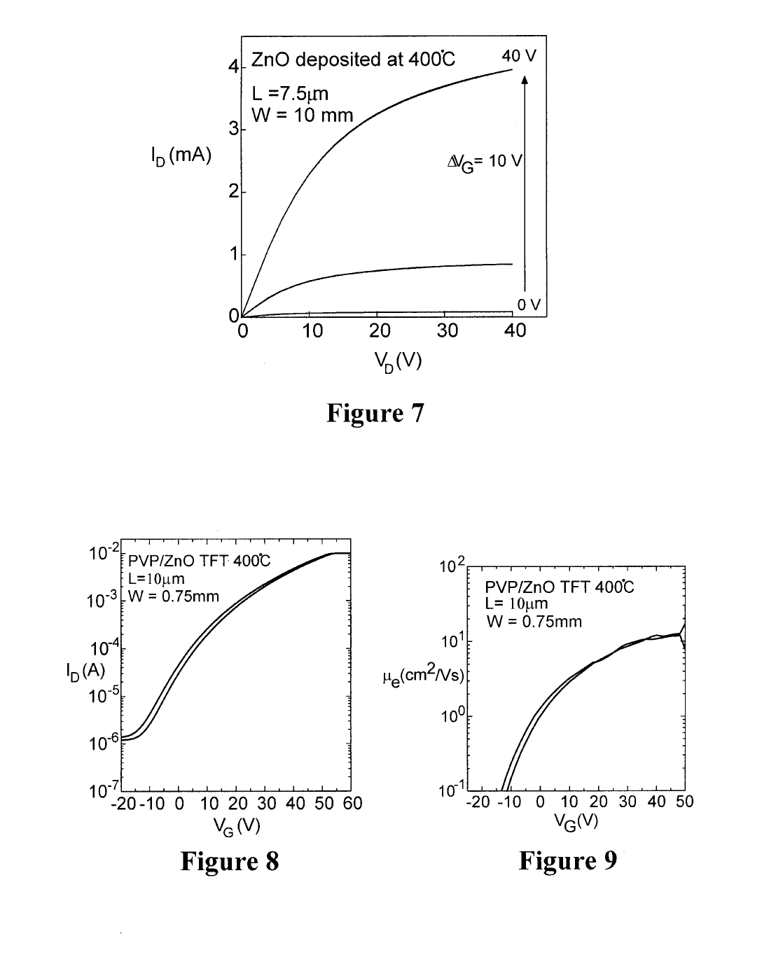

FIGS. 5 to 7 show experimentally-measured output characteristics (drain current [I_{D}] versus drain voltage [V_{D}] at different gate voltages [V_{G}]) for a bottom-gate bottom-contact TFT based on a ZnO film (see FIG. 3a for the specific TFT structure used) deposited by SP at different temperatures (i.e. 200, 300 and 400° C.), using gold source (S) and drain (D) electrodes. The fabrication method was as described above. In each case, the device geometry is included in the figure.

All our ZnO-based devices were found to exhibit electron transport with maximum mobilities in the range 0.1-20 cm²/Vs. The best mobilities were obtained for devices where ZnO was deposited at higher temperatures, i.e. >300° C. However, device fabrication at lower substrate temperatures (T_{S}) i.e. 100<T_{S}<250° C. is also believed to be possible. Thus, we anticipate the SP deposition method to be compatible with processing on plastic substrates (which may be flexible). The same also applies for the SD electrodes.

FIG. 8 shows experimentally-measured transfer characteristics of a bottom-gate bottom-contact TFT (L=10 μm, W=0.75 mm) based on ZnO film deposited by spray pyrolysis at a substrate temperature of 400° C. Here, the drain current I_{D} is plotted against the gate voltage V_{G}.

FIG. 9 shows experimental measurements of mobility dependence on V_{G} for the same bottom-gate bottom-contact TFT as in FIG. 8. This shows electron mobility values of around 13 cm²/Vs.

Bottom-Gate Top-Contact ZnO Transistors

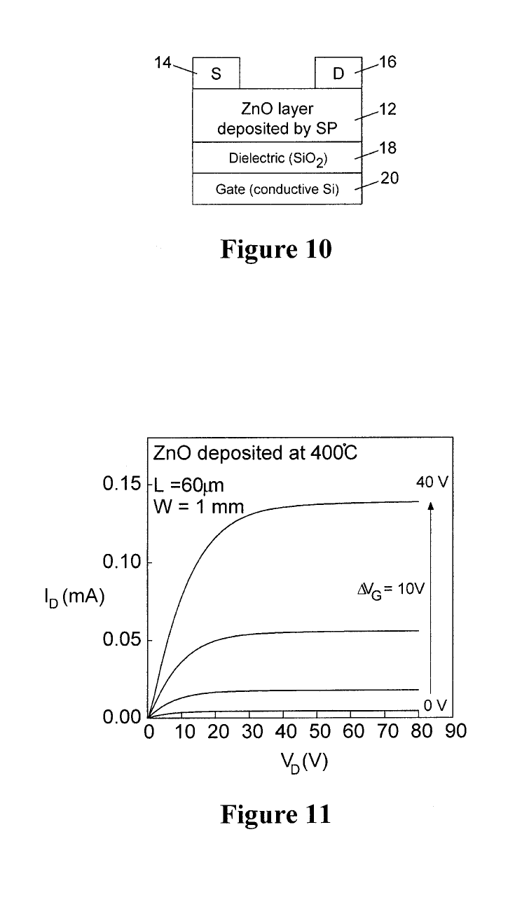

ZnO TFTs based on bottom-gate top-contact architectures have also been realised. The specific bottom-gate top-contact transistor structure employed is shown in FIG. 10.

In the device of FIG. 10, the source electrode 14, drain electrode 16 and gate electrode 20 can be made using either low or high work function metals such as calcium, aluminium, gold, or platinum, to name a few. In principle any materials with high enough conductivity and appropriate physical characteristics could be used, including conductive organics/polymers, or conductive metal oxides. The latter could be attractive for use in transparent electronics. For the gate dielectric a number of potential materials including inorganic insulators such as SiO₂ and insulating metal oxides, as well as organic/polymeric materials, could be employed.

FIG. 11 shows the output curves (drain current [I_{D}] versus drain voltage [V_{D}] at different gate voltages [V_{G}]) for a bottom-gate top-contact ZnO TFT employing aluminium source and drain electrodes. For this specific device the ZnO layer was deposited by SP at 400° C. However a wider range of substrate temperatures could in principle be employed, e.g. 100-600° C. In this work ZnO TFTs were fabricated at substrate temperatures of 200, 300 and 400° C. The highest electron mobility measured was of the order of 10-20 cm²/Vs for devices fabricated at 400° C. The very high value of the carrier mobility is a clear indication of the suitability of SP for the deposition of good quality films, which is unexpected from what is known in the literature.

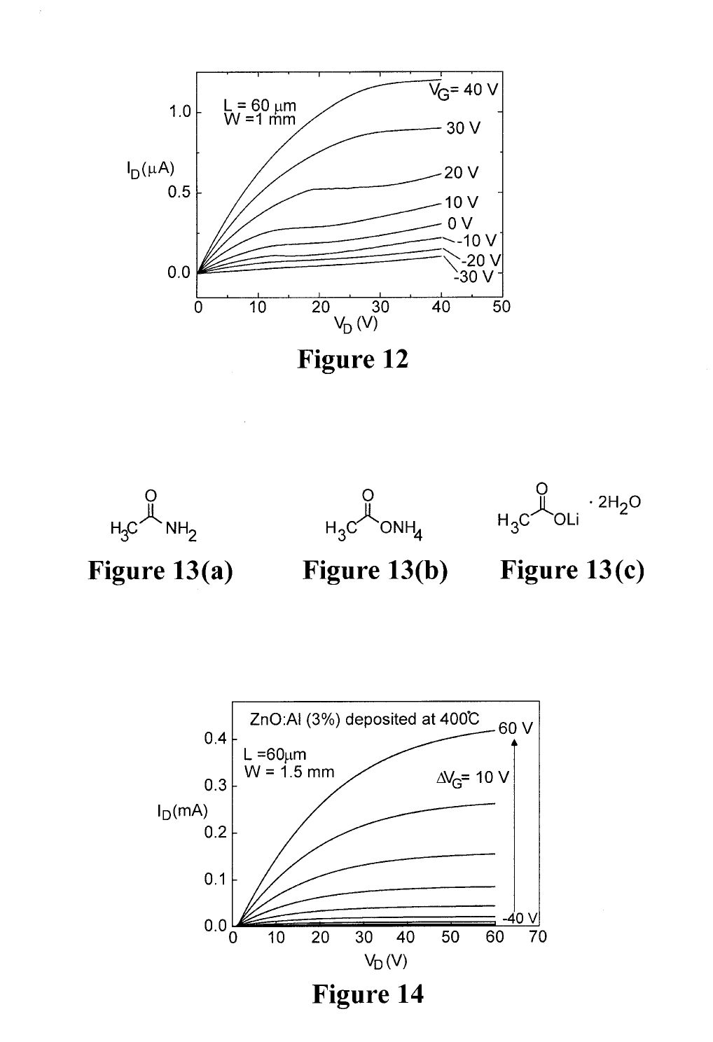

FIG. 12 shows the output characteristics (drain current [I_{D}] versus drain voltage [V_{D}] at different gate voltages [V_{G}]) of a bottom-gate, top-contact TFT comprising a ZnO semiconductor layer deposited by spray pyrolysis at 500° C., employing tin oxide (SnO₂) source and drain electrodes deposited by spray pyrolysis at 300° C. This demonstrates that source and drain electrodes may be deposited by spray pyrolysis, as well as the semiconducting layer, and that the resulting TFT operates well.

Doped Metal Oxide Films Deposited by Spray Pyrolysis

Another important feature associated with the SP technique is the ability to dope the deposited films by means of physical blending of the precursor materials prior to layer deposition. As an example we demonstrate doping of ZnO with aluminium (Al) to produce aluminium zinc oxide (AZO). This work is motivated by the fact that in the literature AZO has been found to exhibit higher charge mobility, and hence its potential for technological applications could be very significant. It should be emphasised that doping is not restricted to Al, and numerous other dopants (known from the literature and hence known to the person skilled in the art) could be employed. Example materials include indium (In), gallium (Ga), molybdenum (Mo), boron (B), nitrogen (N), lithium (Li) and several others. For SP such materials could be introduced in the form of precursor compounds. For instance, one could use the precursor acetamide (FIG. 13(a)) or ammonium acetate (FIG. 13b)) as a source of N; lithium chloride (LiCl) or lithium acetate (FIG. 13(c)) as a source of Li; aluminium nitrate as a source of Al, and so on. In principle there are tens of soluble precursor compounds that could be employed, depending on the physical properties required, e.g. p-doping, n-doping, conductivity enhancement, etc.

Material Preparation and Deposition of AZO Films by SP

The AZO based TFT structure employed is the same as shown in FIG. 10. Doping was performed using zinc acetate blended with aluminium nitrate. Specifically, aluminium nitrate in methanol was added to the starting solution of zinc acetate in the ratio of [Al]/[Zn]=3 at. %. The starting solution was 0.2M of zinc acetate dihydrate in methanol, and then the impurity (i.e. aluminium nitrate) in the ratio mentioned above was added. An AZO layer was formed over a pre-cleaned Si wafer using spray pyrolysis at a substrate temperature in the range 200-400° C.

Specifically, the films were grown in the following manner. After placing the substrate on top of the hot plate, the solution was sprayed vertically above it in a raster fashion for a time duration of 1-50 seconds using an air brush. A time delay of 1-60 seconds was given before the second spray (in a similar manner) to enable the solution vapours to adsorb to the substrate. As those skilled in the art will appreciate, the deposition and delay times may be varied, and the process may be repeated between 1 and 50 (or more) times, depending on the desired properties of the film such as thickness and surface roughness etc.

Aluminium source and drain contacts (25 nm) were thermally evaporated using shadow masks. The resulting channel length and width were 60 μm and 1-1.5 mm, respectively. The output operating characteristics (drain current [I_{D}] versus drain voltage [V_{D}] at different gate voltages [V_{G}]) of a TFT based on an AZO film are displayed in FIG. 14. All the curves illustrate an excellent saturation regime that indicate a good device quality.

Electron mobilities as high as 5 cm²/Vs were obtained from TFTs based on AZO (Al doping of 3%) deposited at 400° C. Although this value is smaller than that obtained from pristine ZnO based TFTs (FIG. 11) it should be possible, through optimisation of the Al concentration, to obtain higher electron mobilities. Another interesting possibility would be the use of appropriate dopants for the creation of hole transporting (p-type) oxide films. Demonstration of both n-channel and p-channel oxide based TFTs will pave the way towards the development of oxide complementary logic circuits and p-n junction devices.

Alternative Device Architectures

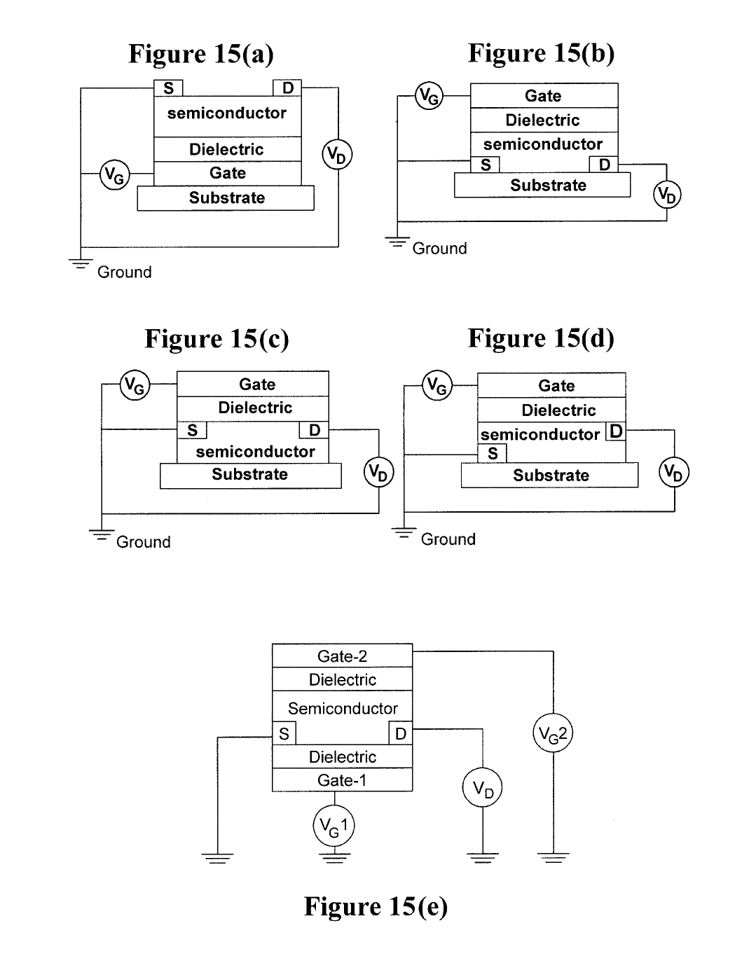

In principle many alternative transistor architectures could be employed, other than the bottom-gate bottom-contact architecture of FIGS. 1 and 3(a), or the bottom-gate top-contact architecture of FIG. 10. Some examples are shown in FIG. 15, which illustrates (a) a bottom-gate top-contact TFT, (b) a top-gate top-contact TFT, (c) a top-gate bottom-contact TFT, (d) a top-gate TFT with asymmetric source-drain contacts, and (e) a double gate TFT. These different device architectures, in combination with different metal electrodes, may be exploited for performance enhancement of the TFT depending on the particular application. Other device architectures are also envisioned and will be familiar to those skilled in the art.

Top-Gate ZnO Transistors

ZnO TFTs based on top-gate architectures have also been realised. The specific top-gate transistor structures employed are shown in FIG. 15(b) and FIG. 15(c).

In the devices of FIG. 15(b) and FIG. 15(c), the source electrode (S), drain electrode (D) and gate electrode (G) can be made using either low or high work function metals such as calcium, aluminium, gold, or platinum, to name a few. In principle any materials with high enough conductivity and appropriate physical characteristics could be used, including metals, conductive organics/polymers (e.g. poly(3,4-ethylenedioxythiophene) poly(styrenesulfonate)—PEDOT-PSS, for short), or conductive metal oxides. The latter could be attractive for use in transparent electronics. For the gate dielectric a number of potential materials could be employed, including inorganic insulators (e.g. SiO₂, Al₂O₃) and other insulating metal oxides as well as organic/polymeric materials such as perfluoropolymers such as CYTOP and HYFLON, to name a few, and various commonly used polymers such as polystyrene and polystyrene derivatives, poly(methyl methacrylate) (PMMA), crosslinkable monomers and polymers, ferroelectric polymers such as polyvinylidene fluoride (PVDF) and its co-polymers such as P(VDF-TrFE) and P(VDF-TFE), to name a few, as well as many other materials known to those skilled in the art.

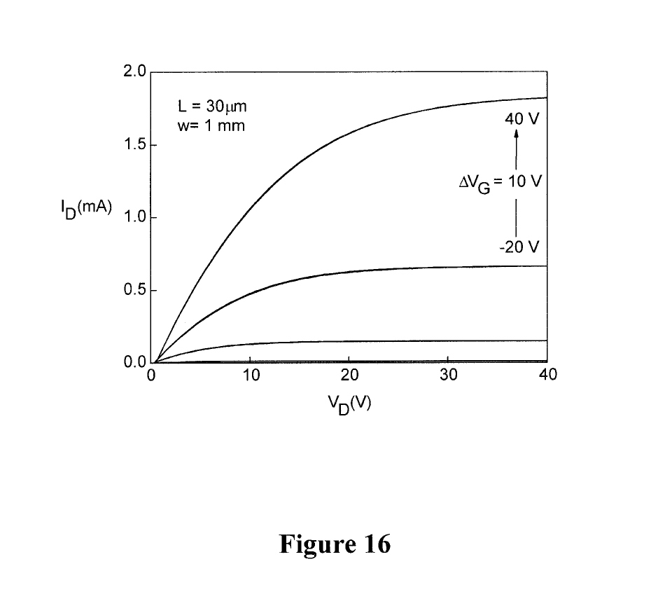

FIG. 16 shows the output curves (drain current [I_{D}] versus drain voltage [V_{D}] at different gate voltages [V_{G}]) for a top-gate ZnO TFT (see FIG. 15(c)) employing aluminium source and drain electrodes, solution processed CYTOP as the gate dielectric, and an evaporated aluminium gate electrode. For this specific device the ZnO layer was deposited by SP at 400° C. However a wider range of substrate temperatures could in principle be employed, e.g. 100-600° C. The highest electron mobility measured for these devices was of the order of 0.01-5 cm²/Vs for transistors fabricated at 400° C. One important point is that the transistor performance can be improved by treating the ZnO surface with oxygen plasma prior to dielectric (CYTOP in this case) deposition. Other plasma ashing techniques may alternatively be used. The time for which the ZnO layer is subjected to oxygen plasma treatment is important and depends on the specific plasma system employed.

This is the first demonstration of a top-gate ZnO TFT fabricated by SP. Such a top-gate structure can be used in memory applications, particularly when combined with ferroelectric polymers such as PVDF derivatives or co-polymers.

1-31. (canceled)

32: A method of forming a thin-film field-effect transistor, the method comprising the steps of:
forming a dielectric layer adjacent a gate;
forming a source region and a drain region; and
forming a semiconductor layer on the dielectric layer;
wherein the semiconductor layer is deposited by spray pyrolysis and comprises a material selected from a group comprising:
oxides; oxide-based materials; mixed oxides; metallic type oxides; group I-IV, II-VI, III-VI, IV-VI, V-VI and VIII-VI binary chalcogenides; and group I-II-VI, II-II-VI, II-III-VI, II-VI-VI and V-II-VI ternary chalcogenides.

33: A method of forming a thin-film field-effect transistor, the method comprising the steps of:
preparing a substrate having a dielectric layer adjacent a gate;
forming a source region and a drain region; and
forming a semiconductor layer on the dielectric layer;
wherein the semiconductor layer is deposited by spray pyrolysis and comprises a material selected from a group comprising:
oxides other than titanium dioxide; oxide-based materials; mixed oxides; metallic type oxides; group I-IV, II-VI, III-VI, IV-VI, V-VI and VIII-VI binary chalcogenides; and group I-II-VI, II-II-VI, II-III-VI, II-VI-VI and V-II-VI ternary chalcogenides.

34: The method as claimed in claim 32, wherein the semiconductor layer is deposited using a precursor solution, the precursor solution being doped in order to incorporate dopant atoms in the semiconductor material once formed.

35: The method as claimed in claim 34, wherein the dopant atoms are selected from a group comprising: aluminum, indium, gallium, molybdenum, boron, nitrogen, and lithium.

36: The method as claimed in claim 32, wherein the spray pyrolysis is performed at a temperature in the range of 100° C. to 400° C.

37: The method as claimed in claim 32, wherein the semiconductor layer is formed of zinc oxide.

38: The method as claimed in claim 32, further comprising depositing the source and/or drain regions, and/or the gate, by spray pyrolysis.

39: The method as claimed in claim 38, wherein the source and/or drain regions, and/or the gate, deposited by spray pyrolysis, is/are formed of a conductive oxide.

40: The method as claimed in claim 39, wherein the conductive oxide comprises a doped metal oxide as one of indium doped tin oxide and aluminum doped zinc oxide.

41: The method as claimed in claim 32, wherein the gate is formed of a conductive polymer.

42: The method as claimed in claim 32, wherein the gate and/or substrate and/or source and drain regions are formed of flexible materials.

43: The method as claimed in claim 32, wherein the dielectric layer is formed of an organic/polymer material.

44: The method as claimed in claim 43, wherein the organic/polymer material is a perfluoropolymer, polystyrene, poly(methyl methacrylate), a crosslinkable monomer or polymer, a ferroelectric polymer, or a derivative or co-polymer of any of the above.

45: The method as claimed in claim 32, wherein the semiconductor layer is deposited before the dielectric layer, and wherein the gate is formed after the dielectric layer, and wherein a surface of the semiconductor layer is treated with plasma prior to the deposition of the dielectric layer.
